(19) United States
(12) Patent Application Publication
(10) Pub. No.: US 2022/0020651 A1
(43) Pub. Date: Jan. 20, 2022

(54) POWER SEMICONDUCTOR MODULE AND MANUFACTURING METHOD FOR POWER SEMICONDUCTOR MODULE

(71) Applicants: NGK Electronics Devices, Inc., Mine-Shi (JP); NGK Insulators, Ltd., Nagoya-Shi (JP)

(72) Inventors: Yuhji UMEDA, Beppu-Shi (JP); Yoshio TSUKIYAMA, Yamaguchi-Shi (JP); Haruhiko ITO, Komaki-Shi (JP)

(73) Assignees: NGK Electronics Devices, Inc., Mine-Shi (JP); NGK Insulators, Ltd., Nagoya-Shi (JP)

(21) Appl. No.: 17/449,692

(22) Filed: Oct. 1, 2021

Related U.S. Application Data
(63) Continuation of application No. PCT/JP2020/013235, filed on Mar. 25, 2020.

(30) Foreign Application Priority Data
May 16, 2019 (JP) 2019-092933

(51) Int. Cl. H01L 23/10; H01L 23/373; H01L 23/053; H01L 23/31; H01L 23/00

(52) U.S. Cl. CPC H01L 23/10; H01L 23/3731; H01L 23/053; H01L 2224/48245; H01L 24/48; H01L 2224/48091; H01L 23/3142

(57) ABSTRACT

A frame is made of a first material. An external terminal electrode is attached to the frame. A heat sink plate supports the frame and includes a mounting region in the frame. The heat sink plate is made of a non-composite material containing copper with purity of 95.0 weight percentage or more. A first adhesive layer bonds the frame and the heat sink plate to each other. The first adhesive layer is made of a second material different from the first material, and has a first composition. A power semiconductor element is mounted on the mounting region of the heat sink plate. A cover is attached to the frame to constitute a sealing space sealing the power semiconductor element without gross leak. A second adhesive layer bonds the frame and the cover to each other, and has a second composition different from the first composition of the first adhesive layer.

### BACKGROUND OF THE INVENTION

### Field of the Invention

The present invention relates to a power semiconductor module and a manufacturing method therefor, and more particularly to a package to constitute a sealing space sealing a power semiconductor element without gross leak when a cover is attached, and the power semiconductor element sealed without gross leak.

### Description of the Background Art

A container that constitutes a sealing space sealing a power semiconductor element may be required to have such high airtightness as not to cause gross leak, depending on a type and use of the power semiconductor element. In particular, sealing without gross leak is in many cases required for a semiconductor element for high frequency. Note that the container that constitutes the sealing space sealing the power semiconductor element when a cover is attached is herein also referred to as a package. The package has a cavity, and when the cavity is sealed by the cover, the sealing space is obtained. The power semiconductor element is mounted on the package in the cavity before the cover is attached to the package.

According to technology of Japanese Patent Application Laid-Open No. 2005-150133, first, a heat sink plate, a ceramic frame, and an external connection terminal are connected to each other. With this, a package having a cavity is prepared. The heat sink plate is made of a composite material. As the composite material, a Cu—W-based composite metal plate, a Cu—Mo-based composite metal plate, and a clad composite metal plate in which a Cu plate is attached to both surfaces of a Cu—Mo-based alloy metal plate are given as examples. The heat sink plate and the ceramic frame are joined together with Ag—Cu brazing at approximately 780° C. to 900° C. The semiconductor element for high frequency is mounted on the package. Then, the cover is bonded to the upper surface part of the ceramic frame, and the cavity is thereby sealed. In other words, the semiconductor element for high frequency is hermetically sealed in the sealing space.

By using a composite material as a material of the heat sink plate as described above, the thermal expansion coefficient of the heat sink plate can be brought closer to the thermal expansion coefficient of the ceramic frame and the semiconductor element. With this, fracture due to a difference of thermal expansion and contraction can be prevented. This allows joining of the ceramic frame and the semiconductor element to the top of the heat sink plate at high temperature. In the above technology, the heat sink plate and the ceramic frame are already joined to each other when the semiconductor element is mounted. In order to mount the semiconductor element so as not to disturb the joining, there is a restriction that the semiconductor element needs to be mounted at a temperature lower than a joining temperature of the ceramic frame. In the above technology, the joining of the ceramic frame is performed at high temperature of approximately 780° C. to 900° C., and thus the joining hardly receives negative influence through heating of the semiconductor element at a mounting temperature. Further, because the thermal expansion coefficient of the heat sink plate is close to the thermal expansion coefficient of the semiconductor element, fracture of the semiconductor element due to a thermal stress during mounting can be avoided even if the mounting temperature is high to some extent. Therefore, mounting of the semiconductor element can be performed with brazing at relatively high temperature for the mounting temperature, for example, approximately 400° C.

According to technology of Japanese Patent Application Laid-Open No. 2003-282751, a Cu or Cu-based metal plate is used as the heat sink plate. Cu is an extremely excellent material in that Cu is relatively inexpensive and yet high thermal conductivity exceeding 300W/m-K can be easily obtained. Thus, unlike the above-described technology of Japanese Patent Application Laid-Open No. 2005-150133 in which the heat sink plate is made of a composite material, a heat sink plate having high thermal conductivity can be obtained at low costs. According to the technology, first, a semiconductor element is mounted on the heat sink plate with brazing. Next, a frame to which the external connection terminal is joined in advance is joined to the top of the heat sink plate so as to surround the semiconductor element. By using a joining member having a low melting point for the joining, the frame is joined at a temperature lower than the brazing temperature of the semiconductor element. Next, when the cover is joined to the upper surface side of the frame, the cavity is sealed. In other words, the semiconductor element is hermetically sealed in the sealing space. With this, a power module for high frequency can be obtained.

According to the technology of Japanese Patent Application Laid-Open No. 2003-282751 described above, by joining the frame to the heat sink plate after mounting the semiconductor element, the cavity of the package is formed. Thus, in the technology, in comparison to the technology of Japanese Patent Application Laid-Open No. 2005-150133 described above, the process after mounting of the semiconductor element is complicated. This is a hindrance to prompt completion of the semiconductor module after mounting of the semiconductor element. This is not preferable for manufacturers of the semiconductor module. Further, the semiconductor module using the package is often subjected to thermal expansion and contraction during use. Thus, not only enabling prompt completion of the power semiconductor module after mounting of the power semiconductor element but also enabling prevention of occurrence of gross leak caused by damage due to difference of thermal expansion and contraction during use is desirable.

### SUMMARY

The present invention is made in order to solve the problem as described above, and has an object to provide a power semiconductor module and a manufacturing method therefor that can enable prompt completion of a power semiconductor module after mounting of a power semiconductor element and can also enable prevention of occurrence of gross leak caused by damage due to difference of thermal expansion and contraction with the use of a heat sink plate having high thermal conductivity.

### Means to Solve the Problem

A power semiconductor module according to the present invention includes a package including an external terminal electrode, a frame, a heat sink plate, and a first adhesive layer, a power semiconductor element, a cover, and a second adhesive layer. The frame is made of a first material. The external terminal electrode is attached to the frame. The heat sink plate supports the frame and includes a mounting region in the frame. The heat sink plate is made of a non-composite material containing copper with purity of 95.0 weight percentage or more. The first adhesive layer bonds the frame and the heat sink plate to each other. The first adhesive layer is made of a second material different from the first material, and has a first composition. The power semiconductor element is mounted on the mounting region of the heat sink plate. The cover is attached to the frame to constitute a sealing space sealing the power semiconductor element without gross leak. The second adhesive layer bonds the frame and the cover to each other, and has a second composition different from the first composition of the first adhesive layer.

A manufacturing method for a power semiconductor module according to the present invention includes the following steps. A step of preparing a package is performed. The package includes an external terminal electrode, a frame to which the external terminal electrode is attached, the frame being made of a first material, a heat sink plate supporting the frame and including a to-be-mounted region in the frame, the heat sink plate being made of a non-composite material containing copper with purity of 95.0 weight percentage or more, and a first adhesive layer bonding the frame and the heat sink plate to each other, the first adhesive layer being made of a second material different from the first material and having a first composition. A step of mounting the power semiconductor element on the to-be-mounted region of the heat sink plate is performed after the step of preparing the package. A step of attaching a cover to the frame to constitute a sealing space sealing the power semiconductor element without gross leak is performed. A step of attaching the cover includes forming a second adhesive layer, the second adhesive layer bonding the frame and the cover to each other and having a second composition different from the first composition of the first adhesive layer.

According to the present invention, the second adhesive layer that bonds the frame and the cover to each other has the second composition different from the first composition of the first adhesive layer. With this, in comparison to the composition of the first adhesive layer, the composition of the second adhesive layer can be made to be a composition appropriate for absorbing the difference of thermal expansion and contraction between the package and the cover. Thus, occurrence of gross leak caused by damage due to the difference of the thermal expansion and contraction can be prevented.

These and other objects, features, aspects and advantages of the present invention will become more apparent from the following detailed description when taken in conjunction with the accompanying drawings.

### BRIEF DESCRIPTION OF THE DRAWINGS

FIG. 1 is a cross-sectional diagram schematically illustrating a configuration of a power semiconductor module according to the first embodiment of the present invention.

FIG. 2 is a cross-sectional diagram schematically illustrating a configuration of a package for the power semiconductor module according to the first embodiment of the present invention.

FIG. 3 is a cross-sectional diagram schematically illustrating a first process of a manufacturing method of the power semiconductor module according to the first embodiment of the present invention.

FIG. 4 is a cross-sectional diagram schematically illustrating a second process of the manufacturing method of the power semiconductor module according to the first embodiment of the present invention.

FIG. 5 is a cross-sectional diagram schematically illustrating a process of a manufacturing method of the package according to the first embodiment of the present invention.

FIG. 6 is a cross-sectional diagram schematically illustrating a configuration of a power semiconductor module according to a comparative example.

FIG. 7 is a cross-sectional diagram schematically illustrating a configuration of a power semiconductor module according to another comparative example.

FIG. 8 is a cross-sectional diagram schematically illustrating a first process of a manufacturing method of the power semiconductor module illustrated in FIG. 7.

FIG. 9 is a cross-sectional diagram schematically illustrating a second process of the manufacturing method of the power semiconductor module illustrated in FIG. 7.

FIG. 10 is a cross-sectional diagram schematically illustrating a modification of the process of the manufacturing method of the package illustrated in FIG. 5.

FIG. 11 is a cross-sectional diagram schematically illustrating a configuration of a power semiconductor module according to the second embodiment of the present invention.

FIG. 12 is a partially enlarged view of FIG. 11.

FIG. 13 is a cross-sectional diagram schematically illustrating a configuration of a package for the power semiconductor module according to the second embodiment of the present invention.

FIG. 14 is a cross-sectional diagram schematically illustrating a first process of a manufacturing method of the power semiconductor module according to the second embodiment of the present invention.

FIG. 15 is a cross-sectional diagram schematically illustrating a second process of the manufacturing method of the power semiconductor module according to the second embodiment of the present invention.

FIG. 16 is a cross-sectional diagram schematically illustrating a third process of the manufacturing method of the power semiconductor module according to the second embodiment of the present invention.

FIG. 17 is a cross-sectional diagram schematically illustrating a fourth process of the manufacturing method of the power semiconductor module according to the second embodiment of the present invention.

### DESCRIPTION OF THE PREFERRED EMBODIMENTS

Embodiments of the present invention will be described below with reference to the drawings.

### First Embodiment

(Configuration)

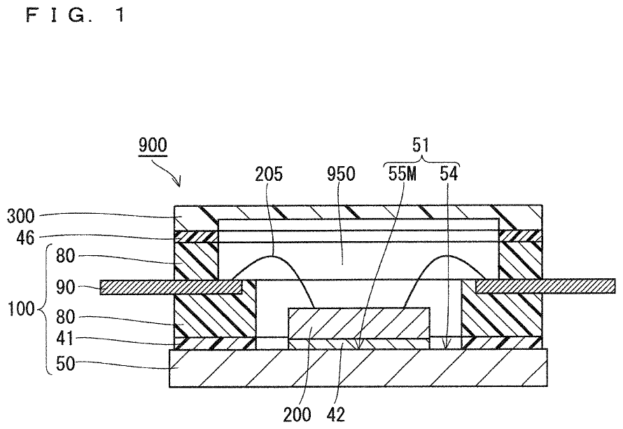

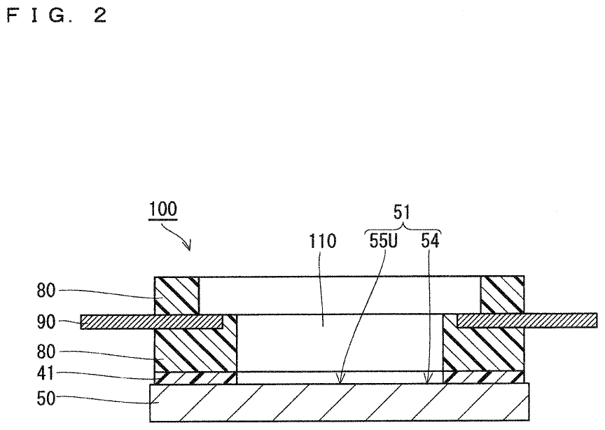

FIG. 1 is a cross-sectional diagram schematically illustrating a configuration of a power semiconductor module 900 according to the present embodiment. The power semiconductor module 900 includes a package 100 (details thereof will be described later reference to FIG. 2), a power semiconductor element 200, and a cover 300. The power semiconductor module 900 further includes an adhesive layer 46 (second adhesive layer) and a joining layer 42.

The power semiconductor element 200 may be a semiconductor element for high frequency. The semiconductor element for high frequency is a semiconductor element that operates with frequencies of approximately from several tens of megahertz (for example, 30 MHz) to 30 GHz. In this case, the power semiconductor module 900 is a high frequency module. Typical examples of the power semiconductor element 200 appropriate for the high frequency use include a lateral diffused MOS (LDMOS) transistor and a gallium nitride (GaN) transistor.

The power semiconductor element 200 is disposed on a mounting region 55M of a heat sink plate 50 of the package 100. It is preferable that the mounting region 55M and the power semiconductor element 200 be joined to each other with the joining layer 42 containing thermosetting resin and metal being interposed therebetween. It is preferable that the thermosetting resin of the joining layer 42 include epoxy resin. It is preferable that the metal of the joining layer 42 include silver.

Although the details will be described later, the package 100 includes the heat sink plate 50 and a frame 80. The heat sink plate 50 includes the mounting region 55M inside the frame 80. In other words, the heat sink plate 50 includes the mounting region 55M surrounded by the frame 80. The power semiconductor element 200 is mounted on the mounting region 55M of the heat sink plate 50.

The cover 300 is attached to the package 100. Specifically, the adhesive layer 46 bonds the frame 80 and the cover 300 to each other. This constitutes a sealing space 950 that seals the power semiconductor element 200 without gross leak. Thus, the power semiconductor element 200 is protected from an external environment with high airtightness so that water vapor and other gases in the atmosphere do not enter. It is preferable that the sealing space 950 have environmental resistance to 500 cycles of temperature changes between −65° C. and +150° C. Specifically, it is preferable that the sealing space 950 not have gross leak even after being exposed to the temperature changes.

FIG. 2 is a cross-sectional diagram schematically illustrating a configuration of the package 100 according to the present embodiment. The package 100 is used for manufacturing of the power semiconductor module 900 (FIG. 1). When the cover 300 (FIG. 1) is attached, the package 100 constitutes the sealing space 950 (FIG. 1). The sealing space 950 (FIG. 1) seals the power semiconductor element 200 (FIG. 1) without gross leak. The package 100 includes a cavity 110 to be the sealing space 950 (FIG. 1). The package 100 includes an external terminal electrode 90, the frame 80, the heat sink plate 50, and an adhesive layer 41 (first adhesive layer).

The frame 80 includes a first material (hereinafter also referred to as a “material of the frame 80”). It is preferable that the material of the frame 80 have heat resistance to thermal treatment at 260° C. for 2 hours. It is preferable that the material of the frame 80 include first resin (hereinafter also referred to as “resin of the frame 80”). It is preferable that the resin of the frame 80 be thermoplastic resin.

It is preferable that an inorganic filler (first inorganic filler) be dispersed in the resin of the frame 80. The inorganic filler in the resin of the frame 80 preferably includes at least one of fiber-like particles and plate-like particles. Owing to the shape being a fiber-like shape or a plate-like shape, when the frame 80 is formed with injection molding technology or the like, the filler is prevented from inhibiting a flow of the resin. Examples of a material of such an inorganic filler include silica glass fibers, alumina fibers, carbon fibers, talc (3MgO, 4SiO₂, H₂O), wollastonite, mica, graphite, calcium carbonate, dolomite, glass flakes, glass beads, barium sulfate, and titanium oxide. As the size of the inorganic filler made of talc on a flat plate, the particle diameter is 1 μm to 50 μm, for example. Here, the particle diameter is an arithmetic mean value of the length of the major axis obtained through cross-sectional observation of resin. It is preferable that the thermal expansion coefficient of the inorganic filler be 17 ppm/K or less, in consideration of the thermal expansion coefficient of copper. It is preferable that the content of the inorganic filler be 30 wt % to 70 wt %.

The external terminal electrode 90 is attached to the frame 80. In the present embodiment, the external terminal electrode 90 is directly attached to the frame 80. The external terminal electrode 90 is made of metal, and preferably contains copper with purity of 90 wt % (weight percentage) or more. Note that, instead of the material containing copper with high purity as described above, Kovar (trademark), iron-nickel alloy, or the like may be used. Note that nickel plating and gold plating on the nickel plating may be provided on the surface of the external terminal electrode 90 for the purpose of securing joinability to a bonding wire 205 or the like.

The heat sink plate 50 supports the frame 80. The heat sink plate 50 is made of a non-composite material containing copper with purity of 95.0 wt % or more, preferably purity of 99.8 wt % or more.

The heat sink plate 50 includes an inner surface 51 surrounded by the frame 80. The inner surface 51 includes a to-be-mounted region 55U in which the power semiconductor element 200 (FIG. 1) is to be mounted, and a peripheral region 54 in which the power semiconductor element 200 is not to be mounted. The to-be-mounted region 55U is a region in which the power semiconductor element 200 is to be mounted although the power semiconductor element 200 is not mounted yet. In other words, a part of the inner surface 51 of the package 100 to be the mounting region 55M (FIG. 1) after the power semiconductor element 200 (FIG. 1) is mounted is the to-be-mounted region 55U. It is preferable that the to-be-mounted region 55U be exposed. The heat sink plate 50 includes an outer surface (lower surface in FIG. 2) on the opposite side of the inner surface 51. The outer surface is usually attached to another member when the power semiconductor module 900 is used; however, the outer surface may be exposed when the power semiconductor module 900 is manufactured.

The adhesive layer 41 bonds the frame 80 and the heat sink plate 50 to each other. The adhesive layer 41 is made of a second material (hereinafter also referred to as a “material of the adhesive layer 41”) different from the material of the frame 80. It is preferable that the material of the adhesive layer 41 include second resin (hereinafter also referred to as “resin of the adhesive layer 41”). It is preferable that the resin of the adhesive layer 41 be thermosetting resin in view of heat resistance and high liquidity before being cured.

It is preferable that an inorganic filler (second inorganic filler) be dispersed in the resin of the adhesive layer 41. The inorganic filler in the resin of the adhesive layer 41 preferably contains at least one of silica glass and crystalline silica, and is more preferably made of silica glass. Typically, the thermal expansion coefficient of silica glass is approximately 0.5 ppm/K, and the thermal expansion coefficient of crystalline silica is approximately 15 ppm/K, and accordingly the thermal expansion coefficient of the inorganic filler can be 17 ppm/K or less. This is particularly desirable when epoxy resin or fluorine resin is used as the resin of the adhesive layer 41. In this case, it is preferable that the content of the inorganic filler be 50 wt % to 90 wt %. Instead of or together with at least one of silica glass and crystalline silica, at least one of alumina, aluminum hydroxide, talc, iron oxide, wollastonite, calcium carbonate, mica, titanium oxide, and carbon fibers may be used. The shape of the inorganic filler is, for example, a spherical shape, a fiber-like shape, or a plate-like shape. In contrast, when silicone resin is used as the resin of the adhesive layer 41, because the silicone resin has rubber elasticity, the restriction of the thermal expansion coefficient of the inorganic filler can be substantially disregarded. In this case, the content of the inorganic filler may be adjusted in view of liquidity control of the adhesive layer 41 or the like, and is preferably 1 wt % to 10 wt %. From the viewpoint of securing liquidity of the adhesive layer 41 before being cured, spherical silica glass (amorphous silica) having a particle diameter of 1 μm to 50 μm is optimal. Here, the particle diameter indicates an arithmetic mean diameter measured through cross-sectional observation of resin.

It is preferable that the elastic modulus of the adhesive layer 41 be from 10 GPa to 20 GPa. As described above, it is preferable that the adhesive layer 41 have an elastic modulus higher than that of a general adhesive layer. This is because, when heat resistance to a thermal load (typically, a load at approximately 260° C. for 2 hours) imposed during a mounting process of the power semiconductor element 200 is to be provided for the package 100, a material having a high elastic modulus is in many cases inevitably selected as the material of the adhesive layer 41. Specifically, to bring the thermal expansion coefficient of the adhesive layer 41 closer to the thermal expansion coefficient (in a case of Cu, approximately 17 ppm/K) of the heat sink plate 50 with the aim of reducing a thermal stress, the elastic modulus of the adhesive layer 41 is in many cases inevitably increased.

The adhesive layer 41 includes a first composition, and the adhesive layer 46 (FIG. 1) has a second composition different from the first composition. Note that, when the inorganic filler is used, difference in the amount of fillers by itself signifies difference in the compositions.

It is preferable that the elastic modulus of the adhesive layer 46 be lower than the elastic modulus of the adhesive layer 41. For example, the elastic modulus of the adhesive layer 46 may be half of the adhesive layer 41 or less. In a strict sense, the elastic modulus of the adhesive layer has temperature dependency; however, in this comparison, the elastic modulus at room temperature (for example, 20° C.) can be used as a standard.

It is preferable that the adhesive layer 41 contain the inorganic filler at a first weight ratio. It is preferable that the adhesive layer 46 contain the inorganic filler at a second weight ratio smaller than the first weight ratio, or not contain the inorganic filler. The inorganic filler is, for example, made of silica glass having a particle diameter of approximately 1 μm to 50 μm. For example, the second weight ratio may be half of the first weight ratio or less.

Bonding using the adhesive layer 41 has airtightness. It is preferable that the airtightness has heat resistance to the thermal treatment at 260° C. for 2 hours. In other words, it is preferable that the airtightness between the heat sink plate 50 and the frame 80 has heat resistance to the thermal treatment at 260° C. for 2 hours. Note that a test as to whether or not the airtightness between the heat sink plate 50 and the frame 80 has heat resistance to the thermal treatment at 260° C. for 2 hours may be carried out by performing a gross leak test, which is carried out by performing the thermal treatment on the package 100 (FIG. 2) at 260° C. for 2 hours and then attaching the cover 300 to the package 100 with sufficient airtightness. When the cover 300 and its attachment structure have sufficient heat resistance, the cover 300 may be attached before the thermal treatment.

It is preferable that the airtightness between the cover 300 and the frame 80 has heat resistance to thermal treatment at 260° C. for 30 seconds. Thus, it is preferable that the adhesive layer 46 has heat resistance to the thermal treatment at 260° C. for 30 seconds. The thermal treatment at 260° C. for 30 seconds is typical thermal treatment in a mounting process of the power semiconductor module 900. Note that, unlike the adhesive layer 41, the adhesive layer 46 is not subjected to heating during the mounting process of the power semiconductor element 200, and thus is not usually required to have such high heat resistance as to be able to tolerate approximately 260° C. for 2 hours.

(Manufacturing Method)

Next, a manufacturing method of the power semiconductor module 900 (FIG. 1) will be described. First, the package 100 (FIG. 2) is prepared.

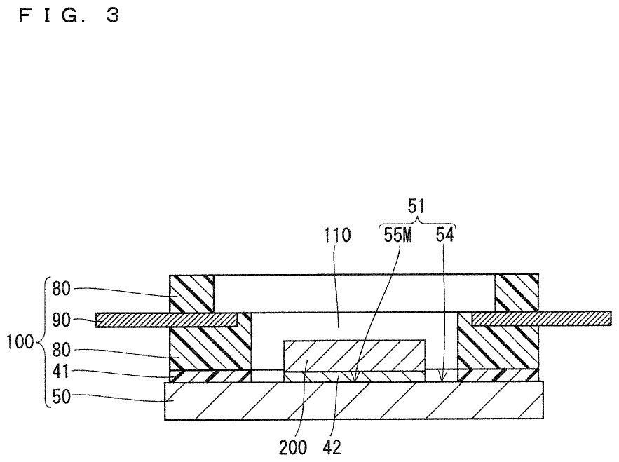

Next, the power semiconductor element 200 is mounted on the to-be-mounted region 55U of the heat sink plate 50. With this, the to-be-mounted region 55U (FIG. 2) that has been exposed becomes the mounting region 55M (FIG. 3) covered by the power semiconductor element 200. When the power semiconductor element 200 is mounted, it is preferable that the to-be-mounted region 55U of the heat sink plate 50 and the power semiconductor element 200 be joined to each other with the joining layer 42 containing thermosetting resin and metal being interposed therebetween. The joining is preferably performed through application of a paste-like adhesive agent containing thermosetting resin and metal, and curing of the paste-like adhesive agent. It is preferable that the thermosetting resin of the joining layer 42 include epoxy resin. It is preferable that the metal of joining layer 42 include silver.

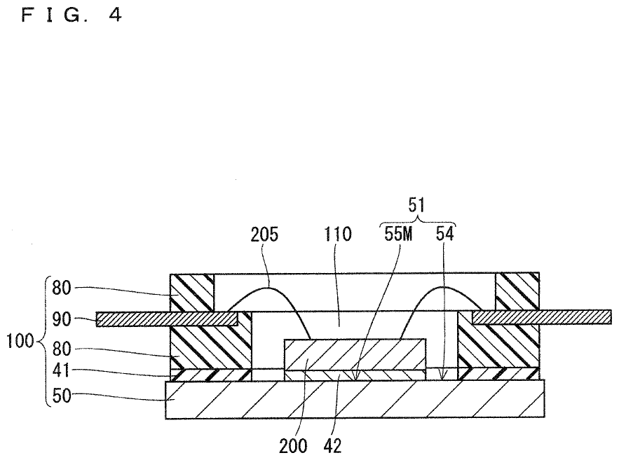

With reference to FIG. 4, next, the power semiconductor element 200 and the external terminal electrode 90 are connected by the bonding wire 205 in the cavity 110. With this, electrical connection between the power semiconductor element 200 and the external terminal electrode 90 is secured. Note that the electrical connection between the power semiconductor element 200 and the external terminal electrode 90 may be secured with a method other than the bonding wire 205, and in that case, the bonding wire 205 is not necessarily required.

With reference to FIG. 1 again, next, the cover 300 is attached to the top of the frame 80, and the power semiconductor element 200 is thereby sealed without gross leak. With this, the power semiconductor module 900 is obtained. Specifically, the adhesive layer 46 that bonds the frame 80 and the cover 300 to each other is formed. Note that a specific process for forming the adhesive layer 46 will be described in the second embodiment to be described later.

Attachment of the cover 300 to the package 100 is performed so that such thermal damage as to cause gross leak is not given to the package 100 in which the power semiconductor element 200 is mounted. In other words, attachment of the cover 300 to the package 100 is performed so that such thermal damage as to cause gross leak is not given to the adhesive layer 41. For example, the cover 300 is attached to the package 100 with interposition of the adhesive layer 46 therebetween, which is cured at such a curing temperature that does not lead to the thermal damage described above. The curing temperature is, for example, less than 260° C.

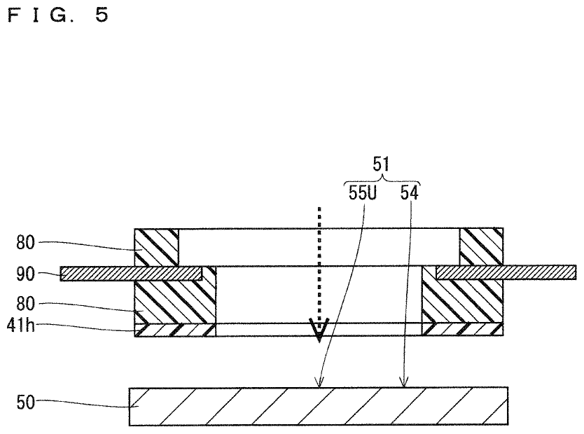

Next, a manufacturing method of the package 100 (FIG. 2) will be described. With reference to FIG. 5, first, the heat sink plate 50 and the frame 80 to which the external terminal electrode 90 is attached are prepared. The frame 80 to which the external terminal electrode 90 is attached can be formed through integral molding of the external terminal electrode 90 made of metal and the frame 80 made of resin. Next, an adhesive agent 41h is applied to the lower surface of the frame 80. Next, as indicated by the broken-line arrow in the figure, the lower surface of the frame 80 is attached to the top of the upper surface of the heat sink plate 50 with the adhesive agent 41h being interposed therebetween. When the adhesive agent 41h is cured, the adhesive layer 41 (FIG. 2) is formed. With this, the package 100 is obtained.

### COMPARATIVE EXAMPLES

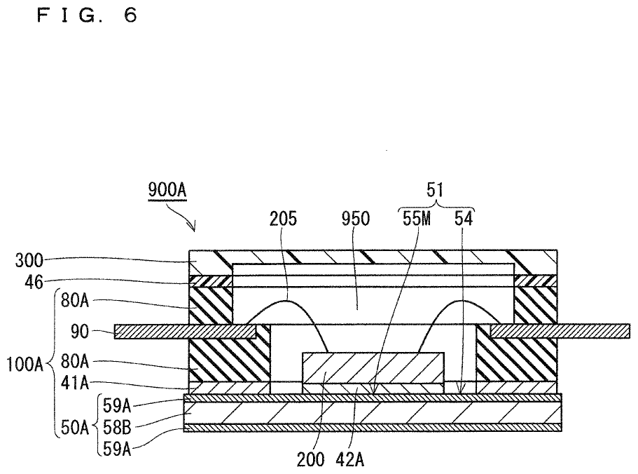

With reference to FIG. 6, a power semiconductor module 900A according to a comparative example includes a package 100A. The package 100A includes a frame 80A, a heat sink plate 50A, and an adhesive layer 41A. The frame 80A is made of ceramics, and thus has high heat resistance. The heat sink plate 50A is made of a composite material. Specifically, the heat sink plate 50A has a stacked structure including a Cu—Mo layer 58B and Cu layers 59A that are provided on the upper surface and the lower surface of the Cu—Mo layer 58B.

By using the above-described composite material as a material of the heat sink plate 50A, the thermal expansion coefficient of the heat sink plate 50A can be brought closer to the thermal expansion coefficients of the frame 80A made of ceramics and the power semiconductor element 200. With this, fracture due to a difference of thermal expansion and contraction can be prevented. This allows joining of the frame 80A and the power semiconductor element 200 to the top of the heat sink plate 50A at high temperature.

In the present comparative example, when the power semiconductor element 200 is mounted, the heat sink plate and the frame are joined to each other, similarly to the present embodiment described above. In order to mount the power semiconductor element 200 so as not to disturb the joining, there is a restriction that the power semiconductor element 200 needs to be mounted at a temperature lower than a joining temperature of the frame 80A. In the present comparative example, the frame 80A itself has high heat resistance and a difference between the thermal expansion coefficient of the frame 80A and the thermal expansion coefficient of the heat sink plate 50A is small, and thus joining between the frame 80A and the heat sink plate 50A can be performed at a high temperature of approximately 780° C. to 900° C. Thus, the joining hardly receives negative influence through exposure to a mounting temperature of the power semiconductor element 200 being a lower temperature. Further, because the thermal expansion coefficient of the heat sink plate 50A is close to the thermal expansion coefficient of the power semiconductor element 200, fracture of the power semiconductor element 200 due to a thermal stress during mounting can be avoided even if the mounting temperature is high to some extent. Therefore, a joining layer 42A for mounting of the power semiconductor element 200 can be formed with brazing at a high temperature of, for example, approximately 400° C.

In the present comparative example, a composite material needs to be used as a material of the heat sink plate 50A for the sake of adjustment of the thermal expansion coefficient. Thus, unlike the case of the heat sink plate 50 (FIG. 1: present embodiment), a non-composite material containing copper cannot be used as a main component. A non-composite material made of high-purity copper is an extremely excellent material in that the non-composite material is relatively inexpensive and yet high thermal conductivity exceeding 300W/m-K can be easily obtained. Such an excellent material cannot be used in the present comparative example. Thus, in the present comparative example, making thermal conductivity of the heat sink plate 50A higher than 300W/m-K is not easy.

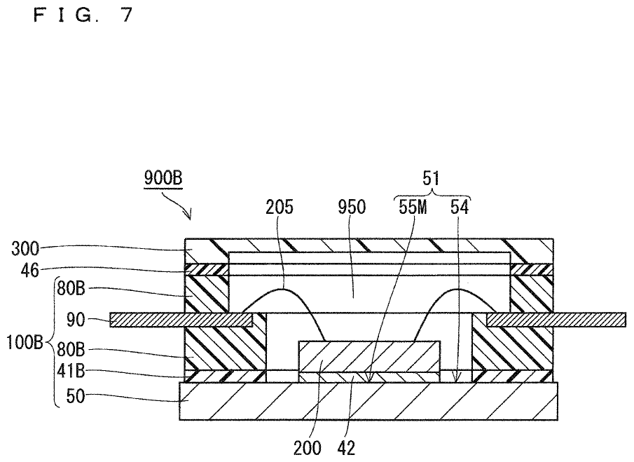

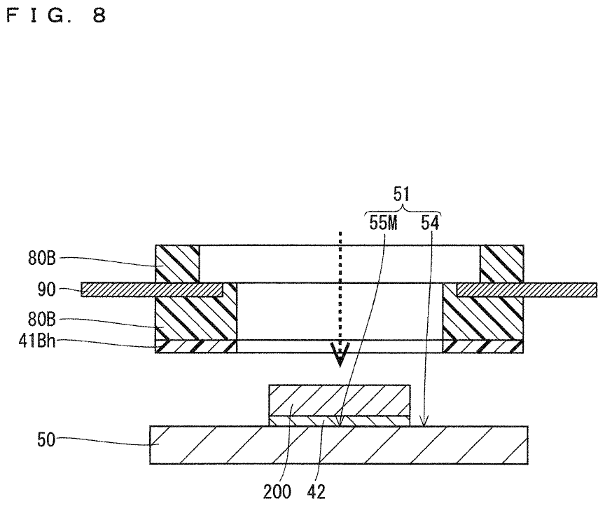

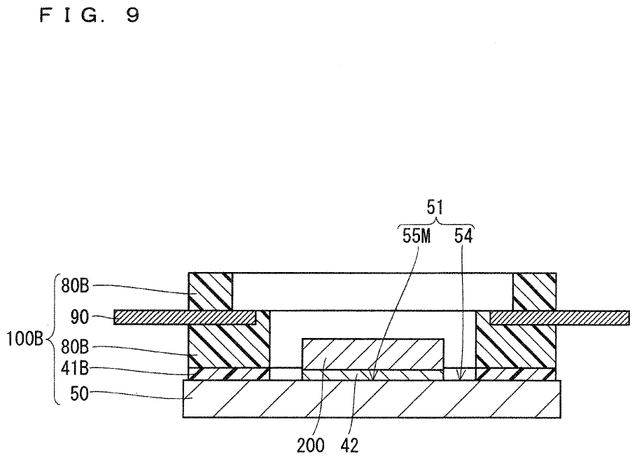

Next, a manufacturing method of a power semiconductor module 900B (FIG. 7) according to another comparative example will be described below. With reference to FIG. 8, first, the power semiconductor element 200 is mounted on the heat sink plate 50 using the joining layer 42. Next, an adhesive agent 41Bh is applied to the lower surface of a frame 80B. Next, as indicated by the broken-line arrow in the figure, the lower surface of the frame 80B is attached to the top of the upper surface of the heat sink plate 50 with the adhesive agent 41Bh being interposed therebetween. When the adhesive agent 41Bh is cured, an adhesive layer 41B (FIG. 9) is formed. With this, the package 100 is obtained. Next, when the cover 300 is joined to the upper surface side of the frame 80B similarly to the present embodiment described above, the power semiconductor module 900B is obtained.

In the present comparative example, the power semiconductor element 200 has already been mounted with the joining layer 42 (FIG. 8) before the frame 80B is attached with the adhesive layer 41B (FIG. 9). Thus, the adhesive layer 41B and the frame 80B are not exposed to high temperature treatment for mounting of the power semiconductor element 200. Thus, a structure and a material of the adhesive layer 41B and the frame 80B can be determined without requiring much consideration on heat resistance. While there are advantages as described above, the present comparative example requires a process of bonding the frame 80B after mounting of the power semiconductor element 200. Thus, the process after mounting of the power semiconductor element 200 is complicated. This is a hindrance to prompt completion of the power semiconductor module 900B after mounting of the power semiconductor element 200. This is not preferable for manufacturers of the power semiconductor module 900B.

(Gist of Effects)

According to the present embodiment, the heat sink plate 50 (FIG. 1) is made of a non-composite material containing copper with purity of 95.0 wt % or more. With this, high thermal conductivity exceeding 300W/m-K can be easily obtained. For example, with a material (containing copper with purity of 99.82 wt % or more) according to Japanese Industrial Standards (JIS) C 1510, high thermal conductivity of 347W/m-K can be obtained. Further, before mounting of the power semiconductor element 200, the heat sink plate 50 includes, in the frame 80, the to-be-mounted region 55U (FIG. 2) in which the power semiconductor element 200 is to be mounted. In other words, when the power semiconductor element 200 is mounted, the frame 80 has already been attached to the top of the heat sink plate 50. Thus, a process of attaching the frame 80 to the top of the heat sink plate 50 after mounting of the power semiconductor element 200 is not required. From the above, with the use of the heat sink plate 50 having high thermal conductivity, the power semiconductor module 900 can be promptly completed after mounting of the power semiconductor element 200.

The adhesive layer 46 that bonds the frame 80 and the cover 300 to each other has the second composition different from the first composition of the adhesive layer 41. With this, in comparison to the composition of the adhesive layer 41, the composition of the adhesive layer 46 can be made to be a composition appropriate for absorbing the difference of thermal expansion and contraction between the package 100 and the cover 300. Thus, occurrence of gross leak caused by damage due to the difference of the thermal expansion and contraction can be prevented.

The elastic modulus of the adhesive layer 46 is lower than the elastic modulus of the adhesive layer 41. With this, in comparison to the composition of the adhesive layer 41, the composition of the adhesive layer 46 can be made to be a composition appropriate for absorbing the difference of thermal expansion and contraction between the package 100 and the cover 300. On the other hand, since the elastic modulus of the adhesive layer 41 is higher than the elastic modulus of the adhesive layer 46, the thermal expansion coefficient of the adhesive layer 41 can be more easily brought closer to the thermal expansion coefficient of the heat sink plate 50. With this, damage to the package due to a thermal stress can be reduced. The inventors of the present invention arrived at the above-described configuration from the idea that, in order to prevent occurrence of gross leak of the power semiconductor module 900, regarding the adhesive layer 41, compatibility of the thermal expansion coefficient with the heat sink plate 50 is particularly important, while regarding the adhesive layer 46, stress relief due to elasticity of the adhesive layer 46 itself is particularly important.

The elastic modulus of the adhesive layer 41 is 10 GPa to 20 GPa. If the same composition as the composition of the adhesive layer 41 having such a high elastic modulus were applied to the adhesive layer 46, damage is liable to be caused to the power semiconductor module 900, in particular the cover 300 thereof, due to the difference of the thermal expansion and contraction between the package 100 and the cover 300. Further, due to the damage, gross leak may occur. According to the present embodiment, the composition of the adhesive layer 46 is different from the composition of the adhesive layer 41, and thus such a situation as described above can be avoided.

The adhesive layer 46 contains an inorganic filler at the second weight ratio smaller than the first weight ratio, or does not contain an inorganic filler. With this, the elastic modulus of the adhesive layer 46 can be reduced. This can enhance the effect of relieving a thermal stress due to the difference of the thermal expansion coefficient between the package 100 and the cover 300 owing to elasticity of the adhesive layer 46.

The airtightness between the cover 300 and the frame 80 has heat resistance to the thermal treatment at 260° C. for 30 seconds. With this, after the frame 80 and the cover 300 are bonded to each other, a mounting process of the power semiconductor module 900 corresponding to a thermal load as high as the thermal treatment at 260° C. for 30 seconds can be performed.

It is preferable that the airtightness between the heat sink plate 50 and the frame 80 have heat resistance to the thermal treatment at 260° C. for 2 hours. With this, even when the thermal load corresponding to the thermal treatment at 260° C. for 2 hours is applied at the time of mounting of the power semiconductor element 200, the application of the thermal load can be prevented from being a cause of gross leak of the sealing space 950 (FIG. 1).

It is preferable that the sealing space 950 (FIG. 1) have environmental resistance to 500 cycles of temperature changes between −65° C. and +150° C. If the composition of the adhesive layer 46 were the same as the composition of the adhesive layer 41, gross leak is liable to occur because of damage due to the difference of the thermal expansion and contraction between the package 100 and the cover 300 at the time of the temperature cycle. According to the present embodiment, the composition of the adhesive layer 46 is different from the composition of the adhesive layer 41, and thus such a situation as described above can be avoided. With this, the power semiconductor element 200 can be maintained in an airtight atmosphere even under a relatively severe temperature change. Thus, reliability of the power semiconductor element 200 can be more securely maintained.

It is preferable that the to-be-mounted region 55U (FIG. 2) be exposed. With this, the power semiconductor element 200 (FIG. 1) can be easily mounted on the to-be-mounted region 55U (FIG. 2).

It is preferable that the material of the frame 80 include resin. With this, brittle fracture due to a thermal stress from the heat sink plate 50 to the frame 80 is made less liable to occur. It is preferable that the resin of the frame 80 be thermoplastic resin. With this, the frame 80 can be formed with high productivity using injection molding technology or the like. It is preferable that an inorganic filler be dispersed in the resin of the frame 80. With this, the thermal expansion coefficient of the frame 80 can be brought closer to the thermal expansion coefficient of the heat sink plate 50. It is preferable that the inorganic filler of the resin of the frame 80 include at least one of fiber-like particles and plate-like particles. With this, when the frame 80 is formed with injection molding technology or the like, the filler is prevented from inhibiting a flow of the resin.

It is preferable that the material of the adhesive layer 41 include resin. With this, a thermal stress applied from the heat sink plate 50 to the frame 80 through the adhesive layer 41 is relieved. Thus, fracture of the frame 80 due to the thermal stress is made less liable to occur. It is preferable that the resin of the adhesive layer 41 be thermosetting resin. With this, heat resistance of the adhesive layer 41 can be enhanced, and liquidity can be more easily secured before being cured. The liquidity is important in securing productivity of a process of forming the adhesive layer 41. If the liquidity is low, it is difficult to use methods such as printing, dispensing, and spraying. It is preferable that an inorganic filler be dispersed in the resin of the adhesive layer 41. With this, the thermal expansion coefficient of the adhesive layer 41 can be brought closer to the thermal expansion coefficient of the heat sink plate 50. This can prevent fracture due to a thermal stress under a high temperature and under a temperature cycle. As described above, the inorganic filler in the resin of the adhesive layer 41 preferably contains at least one of silica glass and crystalline silica, and is more preferably made of silica glass. With this, the thermal expansion coefficient of the inorganic filler can be 17 ppm/K or less, in consideration of the thermal expansion coefficient of copper.

When the power semiconductor element 200 is mounted, it is preferable that the to-be-mounted region 55U (FIG. 2) of the heat sink plate 50 and the power semiconductor element 200 be joined to each other, with the joining layer 42 (FIG. 1) containing thermosetting resin and metal being interposed therebetween. With the joining layer 42 containing metal, performance of heat dissipation from the power semiconductor element 200 to the heat sink plate 50 can be enhanced. Further, with the joining layer 42 containing resin, a thermal stress applied from the heat sink plate 50 to the power semiconductor element 200 through the joining layer 42 is relieved. With this, fracture of the power semiconductor element 200 due to the thermal stress is made less liable to occur.

The external terminal electrode 90 is directly attached to the frame 80. This eliminates the need of the process of bonding the external terminal electrode 90 and the frame 80 to each other. Thus, a process of assembling the package 100 can be simplified.

(Modifications)

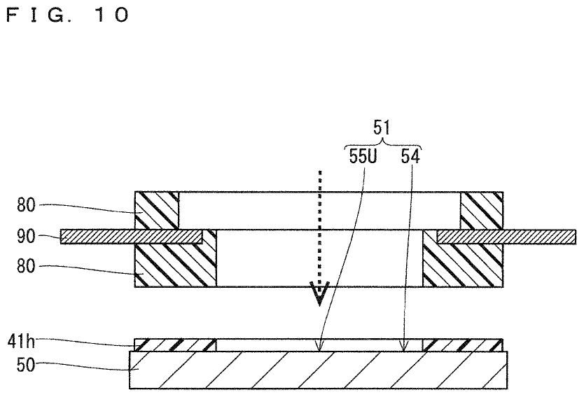

FIG. 10 is a cross-sectional diagram schematically illustrating a modification of a process of the manufacturing method of the package 100 (FIG. 5). In the present modification, the adhesive agent 41h is applied not to the lower surface of the frame 80 but to the upper surface of the heat sink plate 50. Other than the above, the same process as that of the present embodiment described above is performed. Note that the adhesive agent 41h may be applied to both of the lower surface of the frame 80 and the upper surface of the heat sink plate 50.

### Second Embodiment

(Configuration)

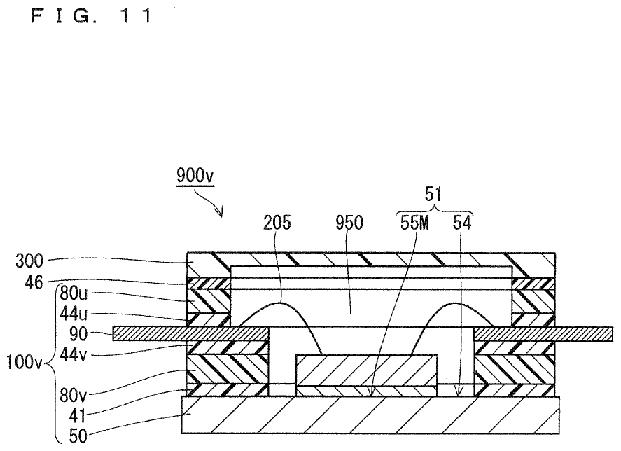

FIG. 11 is a cross-sectional diagram schematically illustrating a configuration of a power semiconductor module 900v according to the present embodiment. In the present embodiment, a package 100v is used instead of the package 100 (FIG. 2).

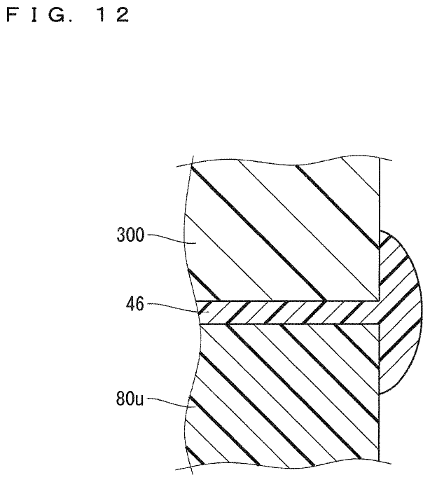

FIG. 12 is a partially enlarged view of FIG. 11. The thickness of the adhesive layer 46 is, for example, 250 μm to 400 μm. With the thickness being 250 μm or more, the thermal stress relief effect owing to elasticity of the adhesive layer 46 is more sufficiently obtained. Further, with the thickness being 400 μm or less, extrusion of the adhesive layer 46 (see FIG. 12) can be prevented.

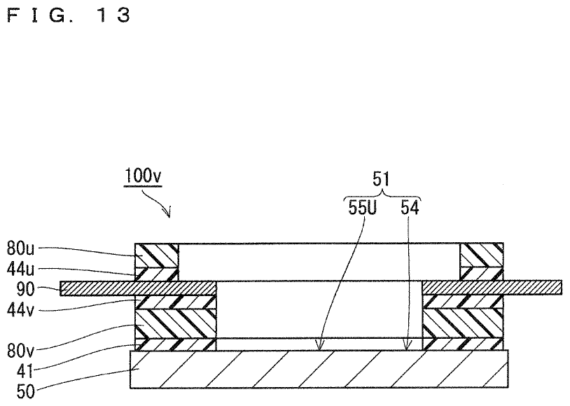

FIG. 13 is a cross-sectional diagram schematically illustrating a configuration of the package 100v. In the present embodiment, the lower surface of the external terminal electrode 90 is attached to a frame 80v with an adhesive layer 44v (third adhesive layer). Specifically, the package 100v includes the adhesive layer 44v that bonds the external terminal electrode 90 and the frame 80v to each other. Further, an additional frame 80u is attached to the upper surface of the external terminal electrode 90 with an adhesive layer 44u. The adhesive layer 44v has a third composition different from the second composition of the adhesive layer 46. The third composition may be the same as the first composition of the adhesive layer 41. A preferable material of the adhesive layer 44u is the same as that of the case of the adhesive layer 44v. It is preferable that the materials of both the adhesive layers be the same. A preferable material of the additional frame 80u is the same as that of the case of the frame 80v. It is preferable that the materials of both the frames be the same. According to the present embodiment, technology of integrally molding the external terminal electrode 90 made of metal and the frame 80 (FIG. 2) made of resin is not required. Note that, provided that the cover 300 (FIG. 11) can be attached with sufficient strength, the additional frame 80u and the adhesive layer 44u may be omitted.

(Manufacturing Method)

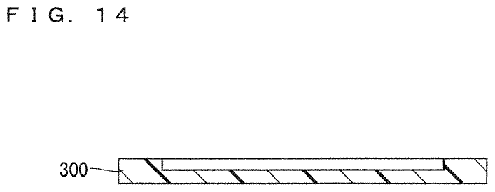

Next, a manufacturing method of the power semiconductor module 900v (FIG. 11) will be described. First, the package 100v (FIG. 13) and the cover 300 (FIG. 14) are prepared. Next, a process of attaching the cover 300 to the package 100v is performed as follows.

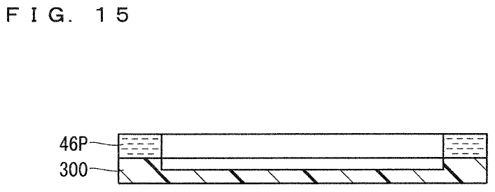

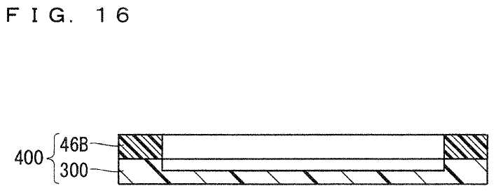

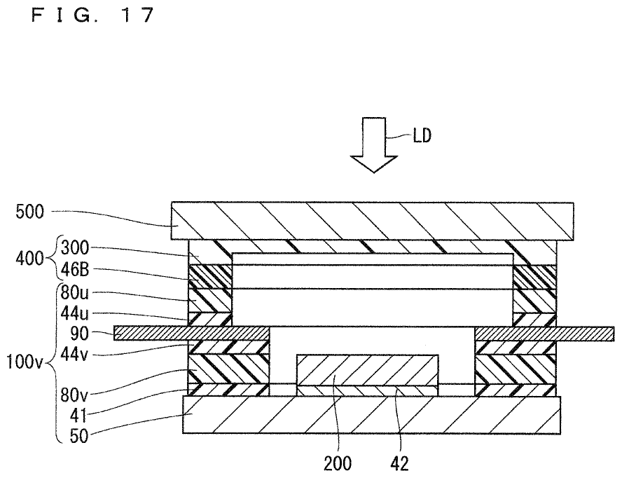

With reference to FIG. 15, a paste layer 46P to ultimately be the adhesive layer 46 (FIG. 11) is applied onto the cover 300. With reference to FIG. 16, the paste layer 46P is cured half, and a half-cured layer 46B is thereby formed. The progress state of curing of the half-cured layer 46B is a state often referred to as “B stage”. With reference to FIG. 17, the cover 300 provided with the half-cured layer 46B is disposed on the package 100v in such a manner that the half-cured layer 46B faces the package 100v. Next, for example, with use of a weight 500, a load LD of pressing the cover 300 and the package 100v to each other is applied. Under the load LD, the half-cured layer 46B is heated. With the heating, curing of the half-cured layer 46B further progresses on the additional frame 80u of the package 100v. With this, the half-cured layer 46B changes to the adhesive layer 46 (FIG. 11).

From the above, the additional frame 80u of the package 100v and the cover 300 are bonded to each other. With this, the power semiconductor module 900v (FIG. 11) is obtained.

Note that the above process can also be applied to the above-described first embodiment in substantially the same manner.

(Gist of Effects)

According to the present embodiment as well, the effects substantially the same as those of the first embodiment can be obtained.

The adhesive layer 44v has the third composition different from the second composition of the adhesive layer 46. With this, in comparison to the composition of the adhesive layer 44v, the composition of the adhesive layer 46 can be made to be a composition appropriate for absorbing the difference of thermal expansion and contraction between the package 100v and the cover 300. Thus, occurrence of gross leak caused by damage due to the difference of the thermal expansion and contraction can be prevented.

The third composition of the adhesive layer 44v may be the same as the first composition of the adhesive layer 41. Through such a common use of the compositions, the manufacturing process of the package 100v can be simplified.

The process of forming the adhesive layer 46 includes a process of changing the half-cured layer 46B provided on the cover 300 to the adhesive layer 46. With this, when the cover 300 provided with the half-cured layer 46B is prepared in advance, the adhesive layer 46 can be easily formed.

### Working Examples and Reference Examples

First of all, an experiment for evaluating configurations of the package to which the cover is to be attached will be described below (see table 1 and table 2). Note that an experiment for comprehensively evaluating configurations including the cover and its adhesive layer as well as the package will be described later (see table 3).

Table 1 and table 2 below show the configurations of the package and results of a gross leak test performed on the configurations according to working examples (Nos. 1 to 25) and reference examples (Nos. 101 to 120), respectively. In the tables, “adhesive layer” refers to the adhesive layer between the heat sink plate and the frame, and “electrode” refers to the external terminal electrode. [Table 1]

TABLE 1

| | | | | | | | GROSS LEAK |
|---|---|---|---|---|---|---|---|
| | | | | | | | AFTER BEING |
| WORKING | ADHESIVE LAYER | | FRAME | | | | LEFT UNDER |
| EXAMPLE | MAIN | | MAIN | | | ELECTRODE | HIGH |
| No. | COMPONENT | FILLER | COMPONENT | | FILLER | MATERIAL | TEMPERATURE |
| 1 | EPOXY | SILICA | RESIN | LIQUID | CONTAINED | COPPER | NOT |
| | RESIN | GLASS | | CRYSTAL | | | OBSERVED |
| 2 | | | | POLYMER | | KOVAR | NOT |
| | | | | | | | OBSERVED |
| 3 | | NONE | | | | COPPER | NOT |
| | | | | | | | OBSERVED |
| 4 | SILICONE | NONE | | | | COPPER | NOT |
| | RESIN | | | | | | OBSERVED |
| 5 | | SILICA | | | | COPPER | NOT |
| | | | | | | | OBSERVED |
| 6 | FLUORINE | SILICA | | | | COPPER | NOT |
| | RESIN | GLASS | | | | | OBSERVED |
| 7 | EPOXY | SILICA | | POLYPHENYLENE | CONTAINED | COPPER | NOT |
| | RESIN | GLASS | | SULFIDE | | | OBSERVED |
| | | | | (PPS) | | | |
| 8 | | | | POLYARYL- | | COPPER | NOT |
| | | | | ETHERKETONE | | | OBSERVED |
| | | | | (PAEK) | | | |
| 9 | | | | POLY- | | COPPER | NOT |
| | | | | ETHERKETONE | | | OBSERVED |
| | | | | (PEEK) | | | |
| 10 | | | | THERMO- | | COPPER | NOT |
| | | | | PLASTIC | | | OBSERVED |
| | | | | POLYIMIDE | | | |
| | | | | (TPI) | | | |
| 11 | | | | POLYAMIDE- | | COPPER | NOT |
| | | | | IMIDE (PAI) | | | OBSERVED |
| 12 | | | | POLY- | | COPPER | NOT |
| | | | | PHTHALAMIDE | | | OBSERVED |
| | | | | (PPA) | | | |
| 13 | | | | POLY- | NONE | COPPER | NOT |
| | | | | TETRA- | | | OBSERVED |
| | | | | FLUORO- | | | |
| | | | | ETHYLENE | | | |
| | | | | (Teflon) | | | |
| | | | | (PTFE) | | | |
| 14 | | | | POLYIMIDE | | COPPER | NOT |
| | | | | (PI) | | | OBSERVED |
| 15 | SILICONE | SILICA | | POLYPHENYLENE | CONTAINED | COPPER | NOT |
| | RESIN | | | SULFIDE | | | OBSERVED |
| | | | | (PPS) | | | |
| 16 | | | | POLY- | | COPPER | NOT |
| | | | | ARYLETHER- | | | OBSERVED |
| | | | | KETONE | | | |
| | | | | (PAEK) | | | |
| 17 | | | | POLY- | | COPPER | NOT |
| | | | | ETHER- | | | OBSERVED |
| | | | | KETONE | | | |
| | | | | (PEEK) | | | |
| 18 | | | | THERMOPLASTIC | | COPPER | NOT |
| | | | | POLYIMIDE | | | OBSERVED |
| | | | | (TPI) | | | |
| 19 | | | | POLYAMIDE- | | COPPER | NOT |
| | | | | IMIDE (PAI) | | | OBSERVED |
| 20 | | | | POLY- | | COPPER | NOT |
| | | | | PHTHALAMIDE | | | OBSERVED |
| | | | | (PPA) | | | |
| 21 | | | | POLYTETRA- | NONE | COPPER | NOT |
| | | | | FLUOROETHYLENE | | | OBSERVED |
| | | | | (Teflon) (PTFE) | | | |
| 22 | | | | POLYIMIDE (PI) | | COPPER | NOT |
| | | | | | | | OBSERVED |
| 23 | EPOXY | SILICA | CERAMICS | ZIRCONIA | NONE | COPPER | NOT |
| | RESIN | GLASS | | | | | OBSERVED |
| 24 | | | | FORSTERITE | | COPPER | NOT |
| | | | | | | | OBSERVED |
| 25 | | | | ALUMINA | | COPPER | NOT |

OBSERVED

TABLE 2

| | | | | | | | GROSS LEAK |
|---|---|---|---|---|---|---|---|
| REF- | | | | | | | AFTER BEING |
| ERENCE | ADHESIVE LAYER | | | | | | LEFT UNDER |
| EX- | MAIN | | FRAME | | | | HIGH |
| AMPLE | COM- | | MAIN | | | ELECTRODE | TEMPER- |
| No. | PONENT | FILLER | COMPONENT | | FILLER | MATERIAL | ATURE |
| 101 | VINYL | NONE | RESIN | LIQUID | CONTAINED | COPPER | OBSERVED |
| | ACETATE | | | CRYSTAL | | | |
| | RESIN | | | POLYMER | | | |
| 102 | VINYL | NONE | | | | | OBSERVED |
| | CHLORIDE | | | | | | |
| | RESIN | | | | | | |
| 103 | ACRYLIC | NONE | | | | | OBSERVED |
| | RESIN | | | | | | |
| 104 | CELLULOSE | NONE | | | | | OBSERVED |
| | RESIN | | | | | | |
| 105 | UREA | SILICA | | | | | OBSERVED |
| | RESIN | GLASS | | | | | |
| 106 | MELAMINE | SILICA | | | | | OBSERVED |
| | RESIN | GLASS | | | | | |
| 107 | PHENOLIC | SILICA | | | | | OBSERVED |
| | RESIN | GLASS | | | | | |
| 108 | POLY- | SILICA | | | | | OBSERVED |
| | URETHANE | GLASS | | | | | |
| | RESIN | | | | | | |
| 109 | CHLOR- | NONE | | | | | OBSERVED |
| | OPRENE | | | | | | |
| | RESIN | | | | | | |
| 110 | NITRILE | NONE | | | | | OBSERVED |
| | RESIN | | | | | | |
| 111 | MODIFIED | NONE | | | | | OBSERVED |
| | SILICONE | | | | | | |
| | RESIN | | | | | | |
| 112 | URETHANE | NONE | | | | | OBSERVED |
| | RESIN | | | | | | |
| 113 | EPOXY | SILICA | | POLY- | | | OBSERVED |
| | RESIN | GLASS | | AMIDE | | | |
| | | | | (NYLON) | | | |
| | | | | (PA) | | | |
| 114 | | | | POLY- | | | OBSERVED |
| | | | | PHENYL- | | | |
| | | | | ENEETHER | | | |
| | | | | (PPE) | | | |
| 115 | | | | POLY- | | | OBSERVED |
| | | | | ACETAL | | | |
| | | | | (POM) | | | |
| 116 | | | | POLY- | | | OBSERVED |
| | | | | CARBONATE | | | |
| | | | | (PC) | | | |
| 117 | | | | POLY- | | | OBSERVED |
| | | | | SULFONE | | | |
| | | | | (PSU) | | | |
| 118 | | | | POLY- | | | OBSERVED |
| | | | | ETHER- | | | |
| | | | | SULFONE | | | |
| | | | | (PEA) | | | |
| 119 | | | | POLY- | | | OBSERVED |
| | | | | ARYLATE | | | |
| | | | | (PAR) | | | |
| 120 | | | | POLY- | | | OBSERVED |
| | | | | ETHERIMIDE | | | |
| | | | | (PEI) | | | |

The content of the filler of the adhesive layer was 82 wt % in a case of silica glass, and was 5 wt % in a case of silica (crystalline silica). Note that, although detailed description is omitted, it is considered that there is no significant influence even if the content of silica glass is changed within a range of 50 wt % to 90 wt %, instead of 82 wt %. Further, it is considered that there is no significant influence even if the content of silica (crystalline silica) is changed within a range of 1 wt % to 10 wt %, instead of 5 wt %. When a filler for the frame was “contained”, a filler made of talc was added at 46 wt %. It is considered that there is no significant influence even if the content of the filler is changed within a range of 30 wt % to 70 wt %, instead of 46 wt %. As a material of the electrode, copper alloy (Japanese Industrial Standards (JIS) C 1940) or Kovar was used. As the heat sink plate, a copper material according to Japanese Industrial Standards (JIS) C 1510 was used, and the heat sink plate had dimensions of 32 mm×10 mm in plan view and a thickness dimension of 1.7 mm.

A gross leak test was performed on the package of table 1 and table 2 after being left under a high temperature. The leaving of the package under a high temperature was performed by leaving the package in an environment at 260° C. for 2 hours. This heating condition is close to a heating condition in the mounting process of the power semiconductor element.

The gross leak test after leaving of the package under a high temperature was performed on a structure configured in the following manner: a package to which the cover was not attached was left in an environment at 260° C. for 2 hours, and then a cover made of liquid crystal polymer was attached using an adhesive agent at a bonding temperature of 190° C. Note that the bonding is performed merely for the purpose of obtaining a sealed state for the sake of the gross leak test, and it is not suggested that a high thermal load is applied after the bonding. Accordingly, it is only necessary that the composition of the adhesive agent be selected such that leakage does not occur through the adhesive agent itself during the gross leak test. For the sake of convenience, in the present experiment, the same resin as the resin (second resin) of the adhesive layer used to join the heat sink and the frame was used as the adhesive agent. Regarding the gross leak test, specifically, Fluorinert (trademark) being a solvent having a high boiling point was heated to 120° C. f 10° C., and the above-described structure was immersed in the solvent for 30 seconds. Occurrence of a leakage was determined depending on whether or not there were bubbles during the immersion.

In each of No. 101 to No. 120 (table 2), a gross leak was observed after leaving of the package under a high temperature. It is inferred that the reason of the occurrence of the gross leak under the high temperature is because heat resistance of the adhesive layer of No. 101 to No. 120 (table 2) is lower than that of the adhesive layer of No. 1 to No. 25 (table 1).

Next, the experiment for comprehensively evaluating configurations including the cover and its adhesive layer as well as the package will be described below. Table 3 below shows configurations of the power semiconductor module and results of a temperature cycle test performed on the configurations according to working examples (Nos. 201 to 204) and comparative example (Nos. 205 to 208). In the table, “adhesive layer” in the column of “package” refers to the first adhesive layer (corresponding to the adhesive layer 41 of FIG. 11) and the third adhesive layer (corresponding to the adhesive layer 44u and the adhesive layer 44v of FIG. 11), and “adhesive layer” in the column of “attachment of cover” refers to the second adhesive layer (corresponding to the adhesive layer 46 of FIG. 11).

TABLE 3

| | | | | ATTACHMENT | | | |
|---|---|---|---|---|---|---|---|
| | | PACKAGE | | OF COVER | | | |
| | | | FILLER OF | | FILLER OF | TEMPERATURE | |
| | | | ADHESIVE | | ADHESIVE | CYCLE TEST | |
| | | MATERIAL | LAYER | MATERIAL | LAYER | | PART OF |
| | No. | OF FRAME | (wt %) | OF COVER | (wt %) | RESULTS | LEAKAGE |
| WORKING | 201 | LIQUID | 80 | LIQUID | 40 | PASS | N/A |
| EXAMPLE | | CRYSTAL | | CRYSTAL | | | |
| | | POLYMER | | POLYMER | | | |
| | 202 | PPS | 80 | PPS | 40 | PASS | N/A |
| | 203 | PEAK | 80 | PEAK | 40 | PASS | N/A |
| | 204 | PPS | 80 | LIQUID | 40 | PASS | N/A |
| | | | | CRYSTAL | | | |
| | | | | POLYMER | | | |
| COMPARATIVE | 205 | LIQUID | 80 | LIQUID | 80 | FAIL | COVER |
| EXAMPLE | | CRYSTAL | | CRYSTAL | | | |
| | | POLYMER | | POLYMER | | | |
| | 206 | PPS | 80 | PPS | 80 | FAIL | COVER |
| | 207 | PEAK | 80 | PEAK | 80 | FAIL | COVER |
| | 208 | LIQUID | 40 | LIQUID | 40 | FAIL | PACKAGE |
| | | CRYSTAL | | CRYSTAL | | | |
| | | POLYMER | | POLYMER | | | |

As a material of the frame, liquid crystal polymer, PPS, and PEAK in each of which a filler was dispersed was used. The liquid crystal polymer had a thermal expansion coefficient of 12 ppm and an elastic modulus of 11.3 GPa. The PPS had a thermal expansion coefficient of 17 ppm and an elastic modulus of 17.5 GPa. The PEAK had a thermal expansion coefficient of 17 ppm and an elastic modulus of 10 GPa.

As a material of each of the first adhesive layer and the second adhesive layer, a material in which a filler made of silica glass was dispersed in epoxy resin was used. Two types of compositions were used therefor. Specifically, a composition in which a filler made of silica glass was dispersed in epoxy resin at 80 wt % and a composition in which a filler made of silica glass was dispersed in epoxy resin at 40 wt % were used. The former (filler 80 wt %) had a thermal expansion coefficient of 12 ppm/K and an elastic modulus of 17 GPa. The latter (filler 40 wt %) had a thermal expansion coefficient of 120 ppm/K and an elastic modulus of 4 GPa. As a material of the electrode, copper alloy (Japanese Industrial Standards (JIS) C 1940) was used. As the heat sink plate, a copper material according to Japanese Industrial Standards (JIS) C 1510 was used, and the heat sink plate had dimensions of 32 mm×10 mm in plan view and a thickness dimension of 1.7 mm.

Temperature cycles were performed with 500 cycles of temperature changes between −65° C. and +150° C. The temperature cycles are simulation of temperature changes to which the power semiconductor module installed in a severe external environment is exposed. Thus, it is necessary that no gross leak be observed in the package used under a severe external environment after the temperature cycles. Note that the method of the gross leak test itself is the same as the method described above.

Note that liquid crystal polymer was used as a material of the cover. Further, in the present experiment, in order to simplify the experiment, instead of an actual mounting process of the power semiconductor element, a process of performing thermal treatment on the package was performed at 260° C. for 2 hours as a simulation of the mounting process.

From the results of the experiment, it was shown that use of a composition different from the composition of the first adhesive layer and the third adhesive layer as the composition of the second adhesive layer yielded more preferable results of the temperature cycle test. Specifically, it was shown that the elastic modulus of the second adhesive layer was preferably lower than the elastic modulus of the first adhesive layer and the third adhesive layer.

Note that the present experiment is performed using the package (see FIG. 13) including the third adhesive layer (see the adhesive layer 44u and the adhesive layer 44v of FIG. 13); however, it is considered that even when a package (see FIG. 2) not including the third adhesive layer is used, results substantially the same as those of the present experiment are obtained regarding selection of the first adhesive layer and the second adhesive layer.

While the invention has been shown and described in detail, the foregoing description is in all aspects illustrative and not restrictive. It is therefore understood that numerous unillustrated modifications can be devised without departing from the scope of the present invention.

What is claimed is:

1. A power semiconductor module comprising:
a package, the package including
an external terminal electrode,
a frame to which the external terminal electrode is attached, the frame being made of a first material,
a heat sink plate supporting the frame and including a mounting region in the frame, the heat sink plate being made of a non-composite material containing copper with purity of 95.0 weight percentage or more, and
a first adhesive layer bonding the frame and the heat sink plate to each other, the first adhesive layer being made of a second material different from the first material and having a first composition;
a power semiconductor element mounted on the mounting region of the heat sink plate;
a cover attached to the frame to constitute a sealing space sealing the power semiconductor element without gross leak; and
a second adhesive layer bonding the frame and the cover to each other, and having a second composition different from the first composition of the first adhesive layer.

2. The power semiconductor module according to claim 1, wherein
an elastic modulus of the second adhesive layer is lower than an elastic modulus of the first adhesive layer.

3. The power semiconductor module according to claim 1, wherein
an elastic modulus of the first adhesive layer is 10 GPa to 20 GPa.

4. The power semiconductor module according to claim 1, wherein
the first adhesive layer contains an inorganic filler at a first weight ratio, and
the second adhesive layer contains an inorganic filler at a second weight ratio smaller than the first weight ratio, or does not contain the inorganic filler.

5. The power semiconductor module according to claim 1, wherein
each of the frame, the first adhesive layer, and the second adhesive layer contains resin.

6. The power semiconductor module according to claim 1, wherein
the sealing space has environmental resistance to 500 cycles of temperature changes between −65° C. and +150° C.

7. The power semiconductor module according to claim 1, wherein
airtightness between the heat sink plate and the frame has heat resistance to thermal treatment at 260° C. for 2 hours.

8. The power semiconductor module according to claim 1, wherein
airtightness between the cover and the frame has heat resistance to thermal treatment at 260° C. for 30 seconds.

9. The power semiconductor module according to claim 1, further comprising
a third adhesive layer bonding the external terminal electrode and the frame to each other, the third adhesive layer having a third composition different from the second composition of the second adhesive layer.

10. The power semiconductor module according to claim 9, wherein the third composition of the third adhesive layer is same as the first composition of the first adhesive layer.

11. The power semiconductor module according to claim 1, wherein
the external terminal electrode is directly attached to the frame.

12. A manufacturing method for a power semiconductor module, comprising:
preparing a package, the package including
an external terminal electrode,
a frame to which the external terminal electrode is attached, the frame being made of a first material,
a heat sink plate supporting the frame and including a to-be-mounted region in the frame, the heat sink plate being made of a non-composite material containing copper with purity of 95.0 weight percentage or more, and
a first adhesive layer bonding the frame and the heat sink plate to each other, the first adhesive layer being made of a second material different from the first material and having a first composition;
mounting the power semiconductor element on the to-be-mounted region of the heat sink plate after the preparing of the package; and
attaching a cover to the frame to constitute a sealing space sealing the power semiconductor element without gross leak,
the attaching of the cover includes forming a second adhesive layer, the second adhesive layer bonding the frame and the cover to each other and having a second composition different from the first composition of the first adhesive layer.

13. The manufacturing method for the power semiconductor module according to claim 12, wherein
the forming of the second adhesive layer includes:
applying a paste layer on the cover;
forming a half-cured layer by half curing the paste layer; and
changing the half-cured layer to the second adhesive layer by causing curing of the half-cured layer to further progress on the package.
